(19) United States
(12) Patent Application Publication
(10) Pub. No.: US 2020/0183618 A1
(43) Pub. Date: Jun. 11, 2020

(54) NON-VOLATILE MEMORY DEVICES AND METHODS OF OPERATING SAME

(71) Applicant: Samsung Electronics Co., Ltd., Suwon-si (KR)

(72) Inventor: Sung-Min Joe, Seoul (KR)

(21) Appl. No.: 16/435,596

(22) Filed: Jun. 10, 2019

(30) Foreign Application Priority Data
Dec. 10, 2018 (KR) 10-2018-0158090

(51) Int. Cl. G06F 3/06; G11C 16/04; G11C 16/10; G11C 16/08; G11C 11/56

(52) U.S. Cl. CPC G06F 3/0659; G11C 16/0483; G11C 16/10; H01L 27/11556; G11C 11/5628; G06F 3/0604; G06F 3/0679; G11C 16/08

(57) ABSTRACT

A memory device includes a nonvolatile memory cell array having a first string including a first nonvolatile memory cell, and a second string including a second nonvolatile memory cell connected to the first nonvolatile memory cell by a first word line. First data is simultaneously programmed into the first and second memory cells. The first and second strings are electrically connected at respective first ends thereof to a bit line (BL) and electrically connected at respective second ends thereof to a common source line (CSL).

### REFERENCE TO PRIORITY APPLICATION

This application claims priority from Korean Patent Application No. 10-2018-0158090, filed Dec. 10, 2018, and all the benefits accruing therefrom under 35 U.S.C. 119, the disclosure of which is hereby incorporated herein by reference.

### BACKGROUND

### 1. Field of the Invention

The present invention relates to integrated circuit memory devices and, more particularly, to nonvolatile memory devices and methods of operating same.

### 2. Description of the Related Art

In order to implement a neural network system within A.I. (Artificial Intelligence), high-speed MAC (Multiply and Accumulate) computation with high band-width and low power consumption computation are required at the same time. In related art, in the architecture for implementing a neural network system within A.I., implementation of high-speed and low power consumption computation for MAC computation in a NAND flash memory may be difficult.

In order to implement high-speed and low power consumption computation for MAC computation, a frequency of intervention of a CPU and a controller at the time of MAC computation should be reduced. To this end, the data programmed in the NAND flash memory for MAC computation should have integrity.

In order for the data programmed in the NAND flash memory to have integrity, it is typically necessary to reduce unwanted fluctuations in threshold voltages between memory cells when programming in the memory cells within the NAND flash memory. By reducing these unwanted fluctuations, it is possible to widen an interval between the data dispersions programmed in the memory cells.

### SUMMARY

Aspects of the present invention provide a memory cell array which supports reductions in the fluctuation of threshold voltages between the memory cells, to thereby widen the interval between data dispersions programmed in the memory cells.

Aspects of the present invention also provide a non-volatile memory device which supports the reductions in the fluctuation of threshold voltage between memory cells to thereby widen the interval between data programmed in the memory cells.

However, aspects of the present invention are not restricted to the ones set forth herein. The above and other aspects of the present invention will become more apparent to one of ordinary skill in the art to which the present invention pertains by referencing the detailed description of the present invention given below.

According to some embodiments of the present invention, a memory cell array is provided, which includes a first string including a first memory cell, and a second string including a second memory cell connected to the first memory cell by a first word line. A common source line (CSL) is provided, to which the first and second strings are connected. During a write operation, first data is simultaneously programmed into the first and second memory cells.

According to some further embodiments of the present invention, a non-volatile memory device is provided, which includes a memory cell array having a first string including a first memory cell therein, and a second string including a second memory cell connected to the first memory cell by a same word line. A control unit is also provided. The control unit receives input data, classifies at least a part of the input data as first data, and simultaneously programs the first data into the first and second memory cells.

According to additional embodiments of the present invention, a non-volatile memory device is provided with first to third memory cells included in each of respective first to third strings. First to third string select transistors are also included in each of the first to third strings, respectively. A first word line is provided, which connects the first to third memory cells. A control unit is provided, which turns the first and second string select transistors ON for a first section (e.g., first time interval), keeps the third string select transistor in an OFF state for the first section, and applies a program voltage to the first word line for a second section (e.g., second time interval).

### BRIEF DESCRIPTION OF THE DRAWINGS

The above and other aspects and features of the present invention will become more apparent by describing in detail exemplary embodiments thereof with reference to the attached drawings, in which:

FIG. 1 is an exemplary block diagram illustrating a computing device according to some embodiments of the present invention.

FIG. 2 is an exemplary block diagram illustrating a computing NAND device according to some embodiments of the present invention.

FIG. 3 is an exemplary perspective view illustrating the embodiment in which the memory cell array of FIG. 2 is three-dimensionally implemented.

FIG. 4 is an equivalent circuit diagram of the memory cell array of FIG. 3.

FIG. 5 is an exemplary diagram illustrating a threshold voltage dispersion of the memory cell.

FIG. 6 is an exemplary diagram for explaining the threshold voltage dispersion of the memory cell of FIG. 5.

FIG. 7 is an exemplary diagram illustrating a memory cell array according to some embodiments of the present invention.

FIG. 8 is an exemplary diagram illustrating the threshold voltage dispersion of different memory cells.

FIG. 9 is an exemplary diagram illustrating a threshold voltage dispersion according to programming of different memory cells.

FIG. 10 is an exemplary time diagram for applying a simultaneous program according to some embodiments of the present invention.

FIG. 11 is an exemplary diagram illustrating the threshold voltage dispersions according to simultaneous programming of the different memory cells of FIG. 7 according to some embodiments of the present invention.

FIG. 12 is an exemplary diagram illustrating a memory cell array according to some embodiments of the present invention.

FIG. 13 is an exemplary diagram illustrating a control unit according to some embodiments of the present invention.

FIG. 14 is an exemplary diagram of a memory cell array including a switch according to some embodiments of the present invention.

FIG. 15 is an exemplary diagram of a memory cell array that applies simultaneous program to different memory cells according to some embodiments of the present invention.

FIG. 16 is an exemplary diagram of the memory cell array that applies simultaneous program to different memory cells according to some embodiments of the present invention.

FIG. 17 is an exemplary diagram of a memory cell array including a region for applying simultaneous program to different memory cells and a region for applying asynchronous program to different memory cells according to some embodiments of the present invention.

FIG. 18 is an exemplary diagram of a memory cell array that applies simultaneous program to different memory cells according to some embodiments of the present invention.

FIG. 19 is an exemplary diagram of the memory cell array that applies simultaneous program to different memory cells according to some embodiments of the present invention.

### DETAILED DESCRIPTION OF THE EMBODIMENTS

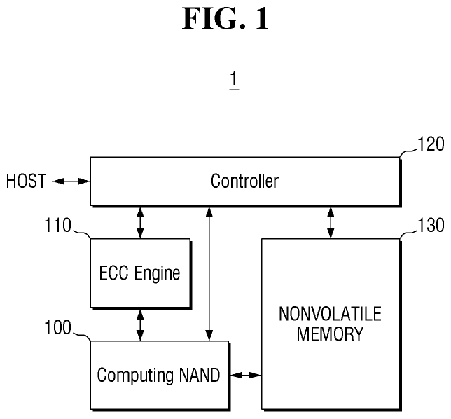

FIG. 1 is an exemplary block diagram illustrating a computing device according to some embodiments of the present invention.

Referring to FIG. 1, a computing device 1 may include a controller 120, an ECC engine 110, a computing NAND device 100, and a non-volatile memory device 130. In some embodiments of the present invention, the non-volatile memory device 130 may include one of a PRAM (phase-change random-access memory), a MRAM (magneto-resistive random access memory), and a RRAM (resistive random-access memory).

The controller 120 may be connected to a host, the non-volatile memory 130 and the ECC engine 110. The controller 200 may be configured to access the non-volatile memory 130 in response to a request from the host. The controller 120 may also be configured to access the computing NAND device 100 via the ECC engine 110. Alternatively, the controller 120 may be configured to directly access the computing NAND device 100. For example, the controller 120 may be configured to control read, write and/or erase operations of the computing NAND device 100.

On the other hand, the controller 120 may be configured to provide an interface between the computing NAND device 100 and the host. Also, the controller 120 may be configured to drive firmware for controlling the computing NAND device 100.

As an example, the controller 120 may further include constituent elements such as a RAM (Random Access Memory), a processing unit, a host interface, and a memory interface. Here, the RAM may be used as at least one of an operating memory of the processing unit, a cache memory between the computing NAND device 100 and the host, and a buffer memory between the computing NAND device 100 and the host. Further, the processing unit may control various operations of the controller 120.

The host interface may include a protocol for performing a data exchange between the host and the controller 120. As an example, the controller 120 may be configured to communicate with outside (host) through at least one of various interface protocols, such as a USB (Universal Serial Bus) protocol, a MMC (multimedia card) protocol, a PCI (peripheral component interconnection) protocol, a PCI-E (PCI-express) protocol, an ATA (Advanced Technology Attachment) protocol, a Serial-ATA protocol, a Parallel-ATA protocol, an SCSI (small computer small interface) protocol, an ESDI (enhanced small disk interface) protocol, and an IDE (integrated drive electronics) protocol.

The memory interface may interface with the computing NAND device 100. Here, the memory interface may include, for example, a NAND interface or a NOR interface. The computing device 1 may also be configured to detect and correct errors of data that are read from the computing NAND device 100, using the ECC engine 110. However, the present invention is not limited thereto, and the ECC engine 110 may be provided as a constituent element of the computing NAND device 100 as necessary.

The ECC engine 110 may correct errors, using an iterative code such as an LDPC (low density parity check) code or a turbo code, but is not limited thereto. The ECC engine using the iterative code performs an iterative operation that repeatedly performs ECC decoding when correcting the error bit. Further, the ECC engine may increase the error bit correction capability, by performing the error bit correction, using the hard decision read data and the soft decision data. In other words, when the ECC engine uses the LDPC code, since the error correction is performed using a log likelihood ratio by the use of the soft decision information, the correction capability is excellent. The ECC engine 110 may include a circuit, a system or a device for error correction.

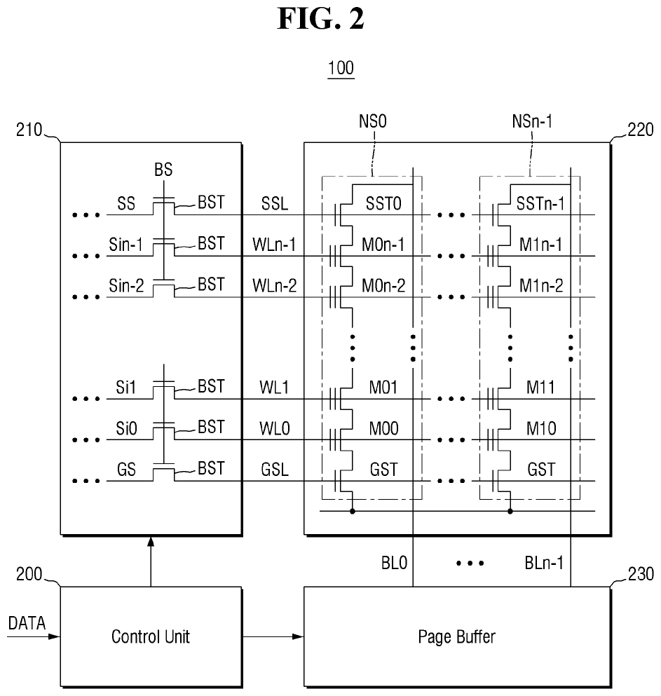

FIG. 2 is an exemplary block diagram illustrating a computing NAND device according to some embodiments of the present invention. Referring to FIG. 2, the computing NAND device 100 may include a control unit 200, a row decoder 210, a memory cell array 220, and a page buffer 230. The rows of the memory cell array 220 may be driven by the row decoder 210, and the columns thereof may be driven by the page buffer 230. The row decoder 210 and the page buffer 230 may be driven by the control unit 200.

The memory cell array 220 may include a plurality of memory cells (M00 to M1n−1). The memory cell block may also be stacked in a three-dimensional (3D) form without being limited to a two-dimensional form. Each memory cell block may include a plurality of memory cell strings (NS0 to NSn−1). Each of the cell strings (NS0 to NSn−1) may include a plurality of memory cells (M00 to M1n−1) for each string. The channels of the memory cells (M00 to M1n−1) of the cell strings (NS0 to NSn−1) may be connected in series between the channels of the plurality of string select transistors (SST) (SST0 to SSTn−1) and the channels of the ground select transistor (GST).

Each block of the memory cell array 220 may include a string select line (SSL), a ground select line (GSL), a plurality of word lines (WL0 to WLn−1), and a plurality of bits Line (BL0 to BLn−1). The string select line may be commonly connected to the gates of the plurality of string select transistors (SST0 to SSTn−1). Each of the plurality of word lines (WL0 to WLn−1) may be commonly connected to the control gates of the corresponding plurality of memory cells (M00 to M1n−1). The ground select line (GSL) may be commonly connected to the gates of the plurality of ground select transistors (GST). Further, the ground select line (GSL), the plurality of word lines (WL0 to WLn−1), and the string select line (SSL) may receive corresponding selection signals (GS, Si0 to Sin−1, and SS) via corresponding block select transistors (BST), respectively. The block select transistors BST may be included in the row decoder 210 and may be connected to be commonly controlled by the block control signal BS.

The row decoder 210 may select one of the plurality of word lines (WL0 to WLn−1) in accordance with the row address information. A word line voltage according to each operation mode may be supplied to the selected word lines and the unselected word lines. For example, the row decoder 210 may supply a program voltage to the selected word line and supply a pass voltage to the unselected word line during the program operation mode. Also, the row decoder 210 may supply the ground voltage (GND) to the selected word line and supply the read voltage to the unselected word lines during the read operation mode. To this end, selection signals (Si0 to Sin−1) may be input to the row decoder 120 from a word line driver. Further, the row decoder 210 may provide a word line voltage to the word lines (WL0 to WLn−1) corresponding to the input selection signals (Si0 to Sin−1). The selection signals (Si0 to Sin−1) may have a voltage level corresponding to at least one of a program voltage, a pass voltage, and a reading voltage. Further, the word line voltage may be provided to the word lines (WL0 to WLn−1) corresponding to the selection signals (Si0 to Sin−1).

The plurality of bit lines (BL0 to BLn−1) arranged on the memory cell array 220 may be connected to the page buffer 230. The page buffer 230 may provide page buffer data corresponding to each of the plurality of bit lines (BL0 to BLn−1). Each page buffer may be implemented to share a pair of bit lines. The page buffer 230 may supply the power supply voltage or the ground voltage to the plurality of bit lines (BL0 to BLn−1) in accordance with the data to be programmed, at the time of the program operation mode. The page buffer 230 may detect data from the selected memory cells through the plurality of bit lines (BL0 to BLn−1) at the time of the reading/verifying operation mode. It is possible to check whether the memory cell is a programmed cell or an erased cell through the detecting operation of the page buffer 230.

The word lines (WL0 to WLn−1) and/or the bit lines (BL0 to BLn−1) connected to the memory cell array 220 may be operated by controlling the row decoder 210 and/or the page buffer 230 (BL0 to BLn−1) through the control unit 200. The control unit 200 may receive data from the controller 120 of FIG. 1, but is not limited thereto.

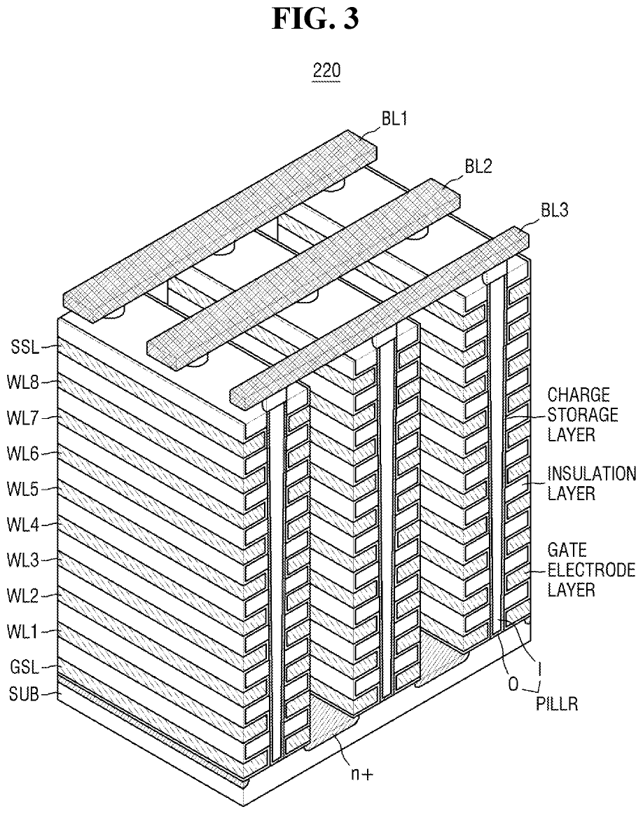

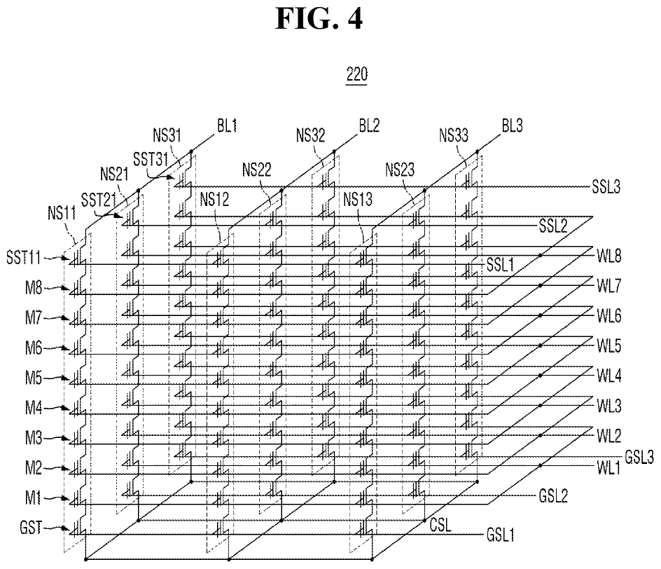

In some embodiments of the present invention, the cell array 220 may be implemented in a two-dimensional structure or a three-dimensional structure. An embodiment in which the cell array 220 is three-dimensionally implemented will be described below with reference to FIGS. 3 and 4.

FIG. 3 is an exemplary perspective view illustrating the embodiment in which the memory cell array of FIG. 2 is three-dimensionally implemented. Referring to FIG. 3, the cell array 220 is formed in a direction perpendicular to a substrate (SUB). An n+ doping region may be formed on the substrate (SUB). A gate electrode layer and an insulation layer may be alternately deposited on the substrate (SUB). Further, a charge storage layer may be formed between the gate electrode layer and the insulation layer.

When the gate electrode layer and the insulation layer are vertically patterned, a V-shaped pillar may be formed. The pillar penetrates the gate electrode layer and the insulation layer and may be connected to the substrate (SUB). An outer shell portion “0” of the pillar may be made of a channel semiconductor, and an inner portion “I” thereof may be made of an insulating material such as silicon oxide.

The gate electrode layer may be connected to a ground select line (GSL), a plurality of word lines (WL1 to WL8), and a string select line (SSL). Further, the pillar may be connected to a plurality of bit lines (BL1 to BL3).

FIG. 3 illustrates a configuration in which the cell array 220 includes a ground select line (GSL), a string select line (SSL), eight word lines (WL1, WL2, . . . , WL8) and three bit lines (BL1, BL2, and BL3), but the number thereof may be larger or smaller than the illustrated case.

FIG. 4 is an equivalent circuit diagram of the memory cell array of FIG. 3. Referring to FIG. 4, in the cell array 220, cell strings (NS11 to NS33) may be connected between the bit lines (BL1, BL2, and BL3) and the common source line (CSL). Each of the cell strings (e.g., NS11) may include a string select transistor (SST) (SST11, SST21, and SST31), a plurality of memory cells (M1, M2, . . . , M8), and the ground select transistor (GST).

The string select transistor (SST) may be connected to the string select line (SSL) (SSL1, SSL2, and SSL3). A plurality of memory cells (M1, M2, . . . , M8) is connected to corresponding word lines (WL1, WL2, . . . , WL8), respectively. The ground select transistor (GST) may be connected to the ground select line (GSL) (GSL1, GSL2, and GSL3). The string select transistors (SST11, SST21 and SST31) may be connected to a bit line (e.g., BL1), and the ground select transistor (GST) may be connected to a common source line (e.g., GSL1).

FIG. 4 illustrates a configuration in which the cell array 220 has a ground select line (GSL), a string select line (SSL), eight word lines (WL1, WL2, . . . , WL8) and three bit lines (BL1, BL2, and BL3), but in reality, the number thereof may be larger or smaller than the illustrated cased.

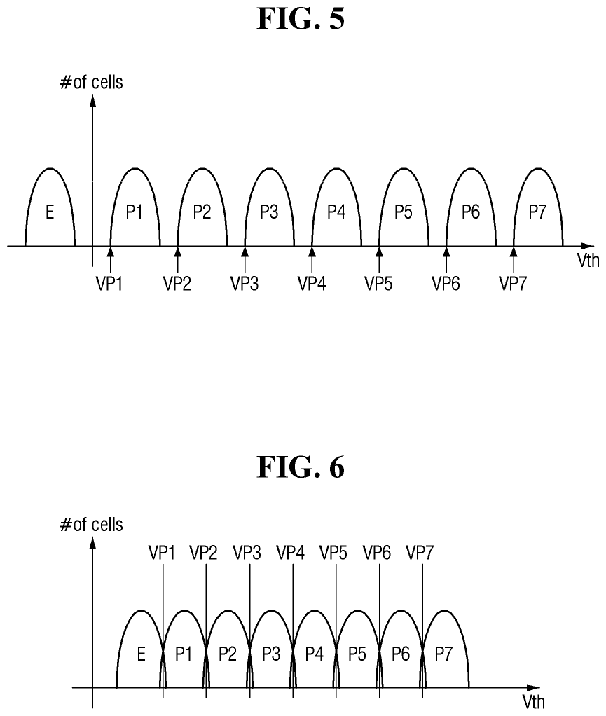

FIG. 5 is an exemplary diagram illustrating a threshold voltage dispersion of the memory cell. Referring to FIGS. 4 and 5, the plurality of memory cells (M1 to M8) of FIG. 4 may be programmed into one of eight unique logical states. That is, each of the plurality of memory cells (M1 to M8) may be configured as a TLC (Triple Level Cell) that stores 3-bit data. An erase state E may represent a state in which a plurality of memory cells (M1 to M8) is erased. The first to seventh logical states (P1 to P7) may represent states into which a plurality of memory cells (M1 to M8) can be programmed. The plurality of memory cells (M1 to M8) may have eight threshold voltage distributions corresponding to eight logical states. The logical states of the plurality of memory cells (M1 to M8) may be discriminated by a large number of verification voltages (VP1 to VP7).

A program operation of the TLC program that stores 3-bit data may be sequentially executed. As an example, the program operation of the lowest bit is executed, and the program operation of the medium bit may be executed thereafter. Subsequently, the program operation of the most significant bit may be executed.

The threshold voltage distribution of each of the logical states (E, and P1 to P7) should maintain a thin state. For example, an interval between a distribution of the fast cells in the threshold voltage distribution of the first logical state P1 and the distribution of the slow cells in the threshold voltage distribution of the second logical state P2 should be wide. Also, an E-UPPER phenomenon (a phenomenon in which the voltage of the erase state E gradually increases) may occur in the continuous program process. Therefore, the interval between the distributions of each of logical states (E, and P1 to P7) should be wide, and movement of the erase state E should be minimized.

The plurality of memory cells (M1 to M8) of FIG. 4 is not limited to a TLC configuration, but may also be a single level cell (SLC), which stores 1 bit of data, or a multi-level cell (MLC), which stores 2 bits of data. In addition, the threshold voltage dispersion is not limited thereto.

FIG. 6 is an exemplary diagram for explaining the threshold voltage dispersion of the memory cell of FIG. 5. Referring to FIGS. 1, 4, and 6, when time elapses after the programming of the plurality of memory cells (M1 to M8) of FIG. 4, characteristic deterioration of the plurality of memory cells (M1 to M8) may occur. If the characteristic deterioration of the plurality of memory cells (M1 to M8) occurs, respective logical states (E, and P1 to P7) may overlap the plurality of verification voltages (VP1 to VP7) which divides the respective logical states (E, and P1 to P7).

This is because of an occurrence of a charge loss in which electrons trapped on a floating gate or a tunnel oxide are emitted as time goes after programming on the plurality of memory cells (M1 to M8). In addition, the tunnel oxide may deteriorate while repeating the program and erase, which may further increase the charge loss. The charge loss may reduce the threshold voltage. For example, the dispersion of the logical state P1 may move to a left side of an original position. Furthermore, the dispersion of each of the logical states (E, and P1 to P7) may be thickened due to program disturbance, erase disturbance, and/or back pattern dependency phenomenon.

The above-described features may be caused by characteristic deterioration of the plurality of memory cells (M1 to M8). Thus, the dispersions of each of the logical states (E, and P1 to P7) may overlap each other. If the threshold voltage dispersions overlap, many data errors may be included in the read data when a specific read voltage is applied. For example, when applying the verification voltage VP2, if there is an on-state, it is required to read the data on the logical state P1 side, and if there is an off-state, it is required to read the data on the logical state P2. However, the logical state P2 overlaps the logical state P1, and the data may be read to the on-state even in the off-state. Therefore, as the dispersions of each of logical states (E, and P1 to P7) overlap, many error bits may be included in the read data.

If many error bits are included in the read data, the errors should be detected using an error detection operation, and then corrected via the ECC engine 110. Further, since the controller 120 intervenes in order for the ECC engine 110 to correct the error, it takes a lot of time. That is, error bits included in the computing NAND device 100 should be minimized for high-speed MAC (Multiply and Accumulate). However, a method of correcting the error is not limited thereto.

Therefore, the interval between the respective logical states (P1 to P7) needs to be sufficiently wide so that the dispersions of each of logical states (E, and P1 to P7) do not overlap each other in accordance with the characteristic deterioration of the plurality of memory cells (M1 to M8). As a result, it is possible to directly execute communication with the controller 120 without going through the ECC engine 110 and execute high-speed MAC computation.

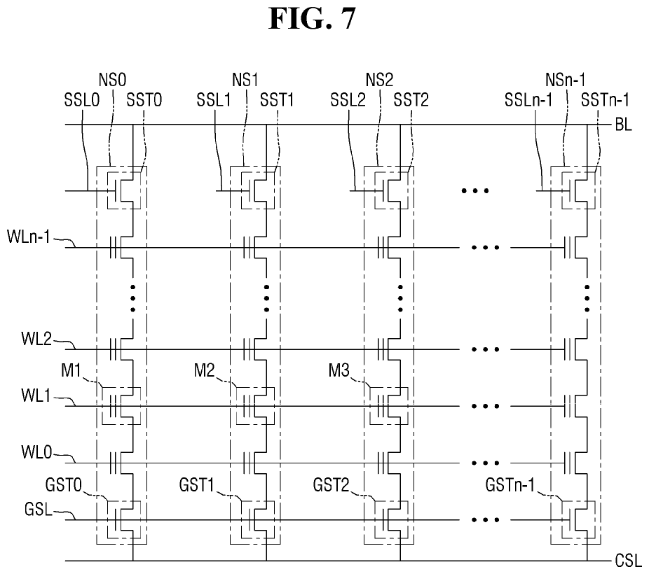

Hereinafter, a scheme of sufficiently expanding the interval between the respective logical states (E, and P1 to P7) will be described through FIGS. 7 to 13.

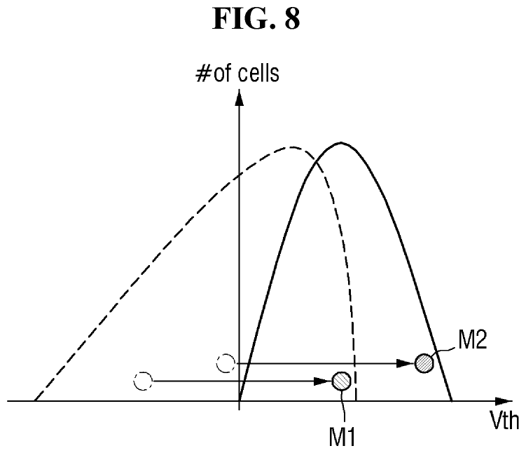

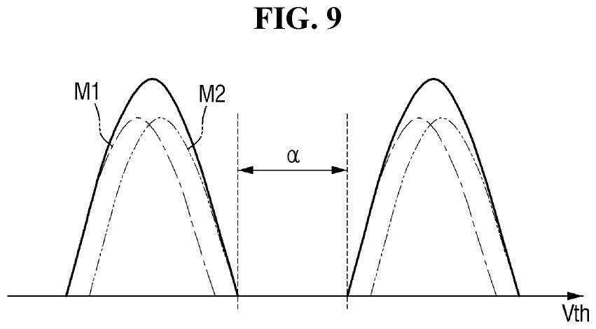

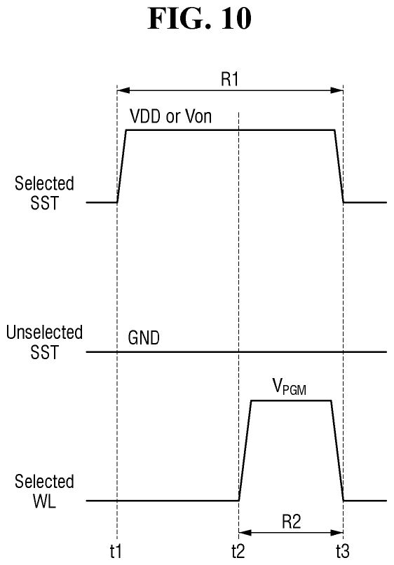

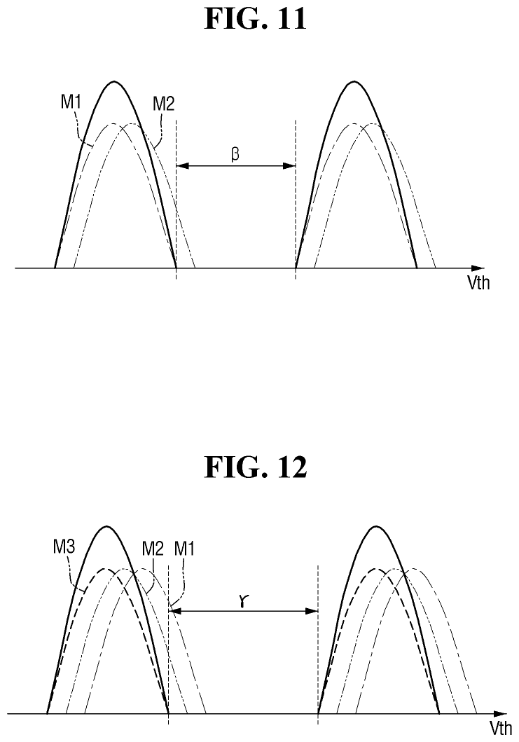

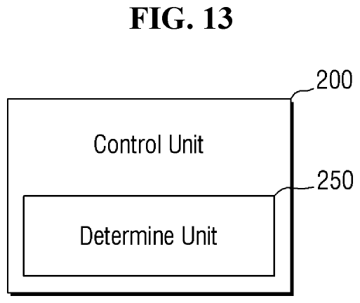

FIG. 7 is an exemplary diagram illustrating a memory cell array according to some embodiments of the present invention. FIG. 8 is an exemplary diagram illustrating the threshold voltage dispersion of different memory cells. FIG. 9 is an exemplary diagram illustrating a threshold voltage dispersion according to programming of different memory cells. FIG. 10 is an exemplary time diagram for applying a simultaneous program according to some embodiments of the present invention. FIG. 11 is an exemplary diagram illustrating the threshold voltage dispersions according to simultaneous programming of the different memory cells of FIG. 7 according to some embodiments of the present invention. FIG. 12 is an exemplary diagram illustrating a memory cell array according to some embodiments of the present invention. FIG. 13 is an exemplary diagram illustrating a control unit according to some embodiments of the present invention.

For reference, repeated parts of the description of the memory cell array 220 of FIG. 2 will be omitted.

Referring to FIGS. 7 and 8, the memory cell array 300 includes a first memory cell M1, a second memory cell M2, and a third memory cell M3. Each of the first memory cell M1, the second memory cell M2, and the third memory cell M3 includes a transistor.

Although the transistors constituting each of the first memory cell M1, the second memory cell M2 and the third memory cell M3 have relatively similar threshold voltages, they may not have completely the same threshold voltage for the reason of the fabricating process. Further, since the transistors constituting each of the first memory cell M1, the second memory cell M2, and the third memory cell M3 are disposed at different positions, they may have different threshold voltages due to external influences.

As an example, the first memory cell M1 and the second memory cell M2 will be described. Even if the same program voltage is applied to the first memory cell M1 and the second memory cell M2, the extent to which the threshold voltage moves may be different between the first memory cell M1 and the second memory cell M2. That is, the dispersion movement of the second memory cell M2 may be faster than the first memory cell M1 with respect to the same program voltage.

For the data program, program voltages may be individually applied to the first memory cell M1 and the second memory cell M2. That is, by asynchronously applying the driving voltage to the first string select line SSL0 and the second string select line SSL1, the program voltage may be individually applied to the first memory cell M1 and the second memory cell M2. In such a case, the dispersion of the first memory cell M1 and the second memory cell M2 is as illustrated in FIG. 9.

Referring to FIG. 9, a first interval (a, alpha) exists between the logical states. At the first interval α, there is still a danger in which the dispersions of the respective logical states overlap each other in accordance with the characteristic deterioration of the plurality of memory cells (e.g., M1, M2, and M3) of the memory cell array 300.

However, when a piece of data is simultaneously programmed in a plurality of memory cells rather than one memory cell, it is possible to obtain a dispersion having an interval wider than the first interval α.

A method of simultaneously programming two memory cells will be described with reference to FIGS. 7 and 10. In particular, a case where data is simultaneously programmed in the first memory cell M1 and the second memory cell M2 will be described.

The first string NS0 includes a first memory cell M1. The first string NS0 is turned on when a driving voltage (VDD or Von) is applied to the first string select transistor SST0. The driving voltage (VDD or Von) may be applied to the first string select transistor SST0 through the first string select line SSL0.

The second string NS1 includes the second memory cell M2. The second string NS1 is turned on when the driving voltage (VDD or Von) is applied to the second string select transistor SST1. The driving voltage (VDD or Von) may be applied to the second string select transistor SST1 through the second string select line SSL1.

The driving voltage (VDD or Von) is applied to the first string select transistor SST0 and the second string select transistor SST1 for the first section R1. The first section R1 may be a section from a first time t1 at which the driving voltage (VDD or Von) is applied to the first string select transistor SST0 and the second string select transistor SST1 to a third time t3 at which the application of the driving voltage to the first string select transistor SST0 and the second string select transistor SST1 is stopped.

A ground voltage may be applied to the remaining string select transistors (for example, the third string select transistor SST2 to the n−1^{st} string select transistor SSTn−1) for the first section R1.

Further, a program voltage V_{PGM} is applied to the second word line WL1 to which the first memory cell M1 and the second memory cell M2 are connected, for the second section R2. The second section R2 may be a section from a second time t2 at which the program voltage V_{PGM} is applied to the second word line WL1 to a third time t3 at which application of the program voltage V_{PGM} to the second word line WL1 is stopped. Thus, data may be simultaneously programmed in the first memory cell M1 and the second memory cell M2.

The first section R1 is not limited to FIG. 10 and may be wider or narrower. The second section R2 is not limited to FIG. 10 and may be wider or narrower and may be formed to be closer to the first time t1.

Dispersion of the case of simultaneously programming the data in two memory cells will be described with reference to FIGS. 7 and 11.

As an example, dispersion of the case of simultaneously programming the data in the first memory cell M1 and the second memory cell M2 will be described.

The dispersion of the case of simultaneously programming the data in the first memory cell M1 and the second memory cell M2 through FIG. 10 may be displayed as illustrated in FIG. 11.

That is, the first memory cell M1 having a relatively low threshold voltage may have a dominant influence on the entire dispersion. For example, since the first memory cell M1 has a low threshold voltage for the same program voltage, a larger current may flow for the same reading voltage. Since the entire dispersion is determined by the first memory cell M1 having a low threshold voltage, a second interval β (beta) between logical states may be wider than the first interval α.

Therefore, dispersions of each logical state may not overlap each other in accordance with characteristics deterioration of the plurality of memory cells. As a result, the computing NAND device 100 of FIG. 1 may communicate directly with the controller 120 without going through the ECC engine 110 to perform high-speed MAC computation.

A method of simultaneously programming three memory cells will be described referring again to FIGS. 7 and 10. In particular, a case where data is simultaneously programmed in the first memory cell M1 to the third memory cell M3 will be described.

The first string NS0 includes a first memory cell M1. The first string NS0 is turned on when the driving voltage (VDD or Von) is applied to the first string select transistor SST0. The driving voltage (VDD or Von) may be applied to the first string select transistor SST0 through the first string select line SSL0.

The second string NS1 includes a second memory cell M2. The second string NS1 is turned on when the driving voltage (VDD or Von) is applied to the second string select transistor SST1. The driving voltage (VDD or Von) may be applied to the second string select transistor SST1 through the second string select line SSL1.

The third string NS2 includes a third memory cell M3. The third string NS2 is turned on when the driving voltage (VDD or Von) is applied to the third string select transistor SST2. The driving voltage (VDD or Von) may be applied to the third string select transistor SST2 through the third string select line SSL2.

The driving voltage (VDD or Von) is applied to the first string select transistor SST0 to the third string select transistor SST2 for the first section R1. The first section R1 may be a section from a first time t1 at which the driving voltage (VDD or Von) is applied to the first string select transistor SST0 to the third string select transistor SST2 to the third time t3 at which the application of the driving voltage to the first string select transistor SST0 to the third string select transistor SST2 is stopped.

A ground voltage may be applied to the remaining string select transistors (for example, the n−1^{St} string select transistor SSTn−1) for the first section R1.

Further, a program voltage V_{PGM} is applied to the second word line WL1 to which the first memory cell M1 to the third memory cell M3 are connected, for the second section R2. The second section R2 may be a section from the second time t2 at which the program voltage V_{PGM} is applied to the second word line WL1 to a third time t3 at which application of the program voltage V_{PGM} to the second word line WL1 is stopped. As a result, data may be simultaneously programmed in the first memory cell M1 to the third memory cell M3.

The first section R1 is not limited to FIG. 10 and may be wider or narrower. The second section R2 is not limited to FIG. 10, may be wider or narrower, and may be formed to be closer to the first time t1.

As an example, the dispersion of the case of simultaneously programming the data in the first memory cell M1 to the third memory cell M3 will be described with reference to FIGS. 7 and 12.

The dispersion of the case of simultaneously programming the data in the first memory cell M1 to the third memory cell M3 through FIG. 10 may be displayed as illustrated in FIG. 12.

As an example, the extent to which the threshold voltage of the third memory cell M3 moves is slower than the extent to which the first memory cell M1 moves.

In other words, the third memory cell M3 having a relatively low threshold voltage may have a dominant influence on the entire dispersion. For example, since the third memory cell M3 has a low threshold voltage for the same program voltage, a larger current may flow for the same reading voltage. Since the entire dispersion is determined by the third memory cell M3 having a low threshold voltage, a third interval γ (gamma) between the logical states may be wider than the second interval β.

Therefore, dispersions of each logical state may not overlap each other in accordance with characteristics deterioration of the plurality of memory cells. As a result, the computing NAND device 100 of FIG. 1 may communicate directly with the controller 120 without going through the ECC engine 110 to perform high-speed MAC computation.

In other words, when simultaneously programming more memory cells for the same data, it is possible to widen the interval between logical states and to improve intensity of data. Therefore, it is possible to improve intensity of data by programming data in more memory cells, with regard to data of relatively high importance.

A determine unit 250 which determines importance will be described with reference to FIG. 13. The control unit 200 may include the determine unit 250.

First, the control unit 200 receives data. The determine unit 250 may determine the importance of the data received by the control unit 200. The determine unit 250 may determine the importance of the data in accordance with the criterion of the importance predetermined by the user in advance. The control unit 200 may determine how many memory cells the data received by the control unit 200 are simultaneously programmed in, on the basis of the importance determined by the determine unit 250. As an example, the control unit 200 may perform program so that, when the importance of the data is top, data is simultaneously programmed in three memory cells, when the importance of the data is medium, data is simultaneously programmed in two memory cells, and when the importance of the data is low, data is programmed in a single memory cell.

However, the method by which the control unit 200 and the determine unit 250 determine the importance of the data and executes the program in accordance with the determined result is not limited thereto. For example, a case where the data received by the control unit 200 is 4-bit data will be described. In the case where it is determined that the foremost bit (for example, representing a sign) is important for the 4-bit data received by the control unit 200, the determine unit 250 may classify the data determined to be important as first data. However, the criterion for determining the importance is not limited thereto.

The determine unit 250 transmits the classified first data to the control unit 200, and the control unit 200 may control the row decoder 210 and/or the page buffer 230 of FIG. 2 to simultaneously program the first data in the three memory cells. However, the number of memory cells in which data is programmed in accordance with determination of importance is not limited thereto.

Hereinafter, repeated parts of the description through FIGS. 7 and 10 will be omitted.

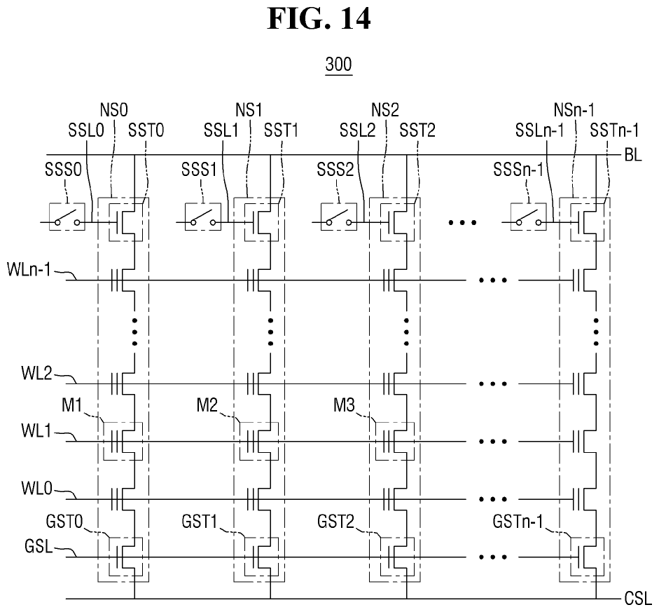

FIG. 14 is an exemplary diagram of a memory cell array including a switch according to some embodiments of the present invention. Referring to FIG. 14, string selection switches (SSS0 to SSSn−1) may be connected to the string select lines (SSL0 to SSLn−1) connected to the gates of each of the string select transistors (SST0 to SSTn−1), respectively.

For example, in order to program data in the first memory cell M1 and the second memory cell M2, the first string selection switch SSS0 and the second string selection switch SSS1 may be turned on, and the same driving voltage may be applied to the first string select line SSL0 and the second string select line SSL1 at the same time. Thereafter, a program voltage may be applied to the second word line WL1 to which the first memory cell M1 and the second memory cell M2 are connected.

As another example, in order to program data in the first memory cell M1 to the third memory cell M3, the first string selection switch SSS0 to the third string selection switch SSS2 are turned on, and the same driving voltage may be applied to the first string select line SSL0 to the third string select line SSL2 at the same time. Thereafter, a program voltage may be applied to the second word line WL1 to which the first memory cell M1 to the third memory cell M3 are connected.

By programming a piece of data in a plurality of memory cells via the string selection switches, a phenomenon in which the dispersions of the respective logical states overlap each other in accordance with the characteristic deterioration of the plurality of memory cells may not occur. As a result, the computing NAND device 100 of FIG. 1 may communicate directly with the controller 120 without going through the ECC engine 110 to perform high-speed MAC computation.

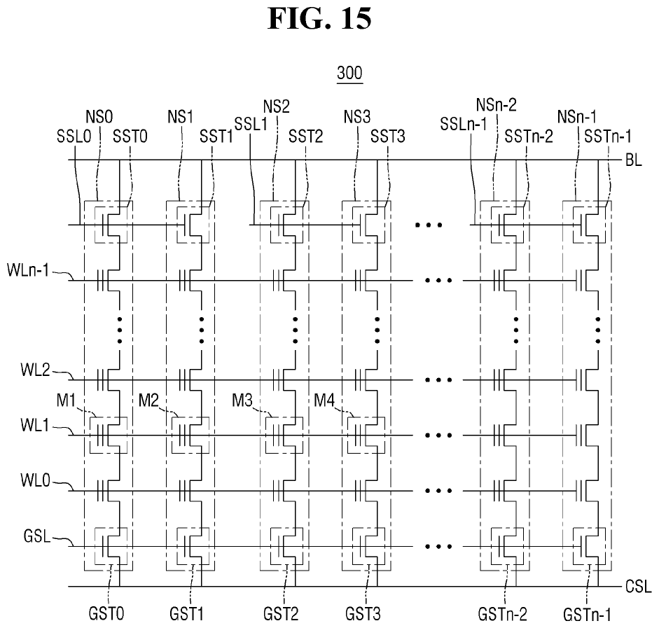

FIG. 15 is an exemplary diagram of a memory cell array that applies simultaneous program to different memory cells according to some embodiments of the present invention. Referring to FIG. 15, in order to simultaneously program data in two memory cells, two gates of the string select transistor may be connected by a single string select line. The two gates may be connected at the stage of the fabricating process.

The first memory cell M1 and the second memory cell M2 are included in the first string NS0 and the second string NS1, respectively. The first string select transistor SST0 and the second string select transistor SST1 which drive each of the first string NS0 and the second string NS1 may be connected to each other by the first string select line SSL0 in the fabricating process.

Therefore, in order to program data in the first memory cell M1 and the second memory cell M2, the driving voltage may be applied to the first string select line SSL0. Thereafter, the program voltage may be applied to the first word line WL1 to which the first memory cell M1 and the second memory cell M2 are connected.

Further, the third memory cell M3 and the fourth memory cell M4 are included in the third string NS2 and the fourth string NS3, respectively. The third string select transistor SST2 and the fourth string select transistor SST3 which drive each of the third string NS2 and the fourth string NS3 may be connected to each other by the second string select line SSL1 in the fabricating process. Therefore, in order to program data in the third memory cell M3 and the fourth memory cell M4, the driving voltage may be applied to the second string select line SSL1. Thereafter, a program voltage may be applied to the first word line WL1 to which the third memory cell M3 and the fourth memory cell M4 are connected.

By connecting the plurality of string select transistors to each other two at a time in the fabricating process and programming a piece of data in two memory cells, a phenomenon in which the dispersions of the respective logical states overlap each other in accordance with the characteristic deterioration of the plurality of memory cells may not occur. As a result, the computing NAND device 100 of FIG. 1 may communicate directly with the controller 120 without going through the ECC engine 110 to perform high-speed MAC computation. The number of string select transistors to be connected is not limited thereto.

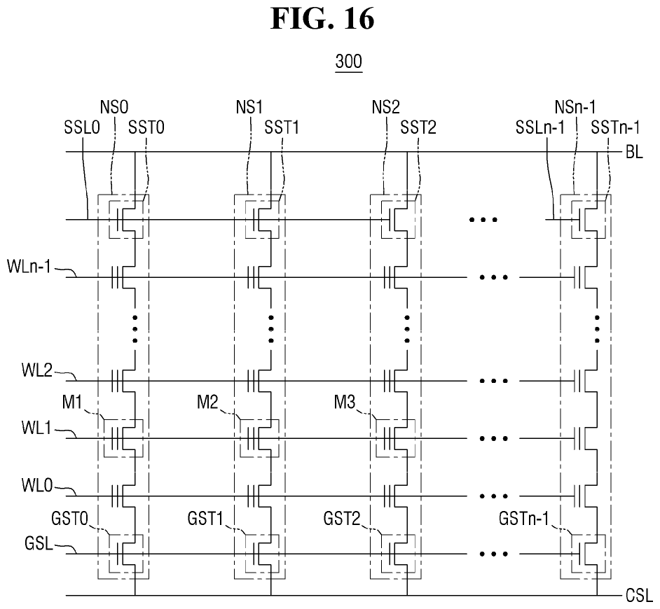

FIG. 16 is an exemplary diagram of the memory cell array that applies simultaneous program to different memory cells according to some embodiments of the present invention. Referring to FIG. 16, in order to simultaneously program data in three memory cells, three gates of the string select transistor may be connected by a single string select line. The three gates may be connected to each other at the stage of the fabricating process.

The first memory cell M1 to the third memory cell M3 are included in the first string NS0 to the third string NS2, respectively. The first string select transistor SST0 to the third string select transistor SST2 which drive each of the first string NS0 to the third string NS2 may be connected to each other by the first string select line SSL0 in the fabricating process.

Therefore, in order to program data in the first memory cell M1 to the third memory cell M3, the driving voltage may be applied to the first string select line SSL0. Thereafter, the program voltage may be applied to the first word line WL1 to which the first memory cell M1 to the third memory cell M3 are connected.

By connecting the plurality of string select transistors three at a time in the fabricating process and programming a piece of data in three memory cells, a phenomenon in which the dispersions of each logical state overlap each other in accordance with characteristic deterioration of the plurality of memory cells may not occur. As a result, the computing NAND device 100 of FIG. 1 may communicate directly with the controller 120 without going through the ECC engine 110 to perform high-speed MAC computation. The number of plurality of string select transistors to be connected is not limited thereto.

Hereinafter, a region in which a piece of data is programmed in two or more memory cells is called a merge region. A region in which a piece of data is programmed only in one memory cell is called a separate region.

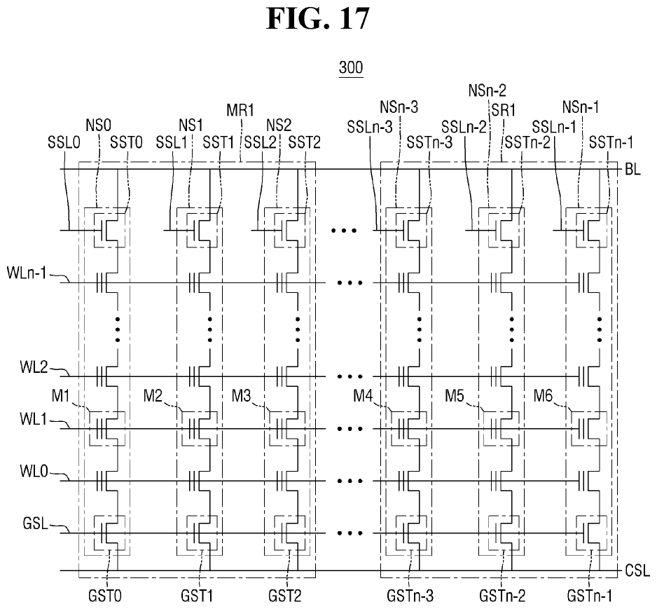

FIG. 17 is an exemplary diagram of a memory cell array including a region for applying simultaneous program to different memory cells and a region for applying asynchronous program to different memory cells according to some embodiments of the present invention. Referring to FIG. 17, the memory cell array 300 includes a first merge region MR1 and a first separate region SR1.

For example, the first merge region MR1 may simultaneously apply the driving voltage to the first string select line SSL0 to the third string select line SSL2 to program a piece of data in the first memory cell M1 to the third memory cell M3. At this time, the data programmed in the first merge region MR1 may be data with high importance among the data used for the MAC computation.

The first separate region SR1 may program separate data in each of separate memory cells (or example, a fourth memory cell M4, a fifth memory cell M5, and a sixth memory cell M6). At this time, the data programmed in the first separate region SR1 may be data of low importance among the data to be used for the MAC computation.

Therefore, in the present embodiment, by determining the importance of the data, and since the data of high importance is programmed in the first merge region MR1, the dispersions of the respective logical states may not overlap each other. As a result, the computing NAND device 100 of FIG. 1 may communicate directly with the controller 120 without going through the ECC engine 110 to perform high-speed MAC computation. Further, since data of low importance may be programmed in the first separate region SR1, it is possible to efficiently utilize the memory cell array 300.

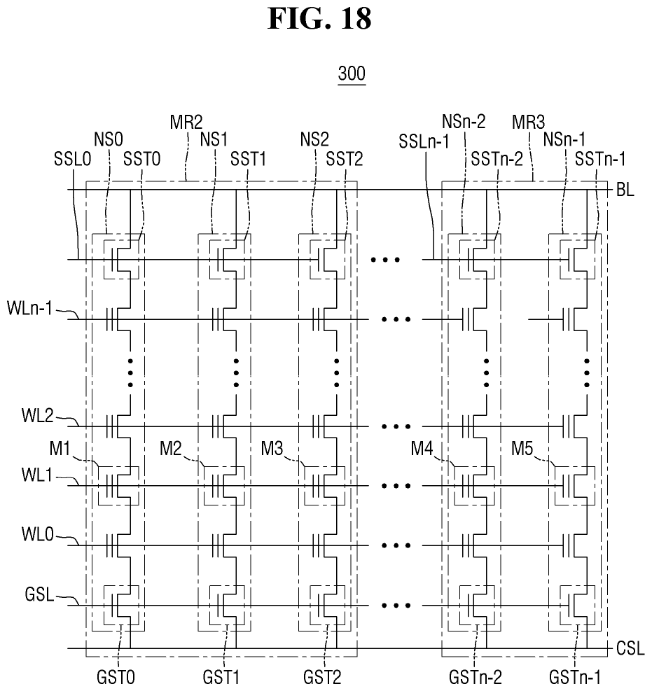

FIG. 18 is an exemplary diagram of a memory cell array that applies simultaneous program to different memory cells according to some embodiments of the present invention. Referring to FIG. 18, the memory cell array 300 includes a second merge region MR2 and a third merge region MR3.

For example, the second merge region MR2 may connect the first string select transistor SST0 to the third string select transistor SST2 to each other by the first string select line SSL0 in the fabricating process in order to program a piece of data in the first memory cell M1 to the third memory cell M3.

The third merge region MR3 may connect the n−2^{nd} string select transistor SSTn−2 to the n−1^{st} string select transistor SSTn−1 by the n−2^{nd} string select line SSLn−2 in the fabricating process in order to program a piece of data in the fourth memory cell M4 and the fifth memory cell M5.

Therefore, in the present embodiment, by determining the importance of the data, since data of importance is programmed in the second merge region MR2, and data of low importance may be programmed in the third merge region MR3, it is possible to efficiently utilize the memory cell array 300. Also, the dispersions of each logical state may not overlap each other. As a result, the computing NAND device 100 of FIG. 1 may communicate directly with the controller 120 without going through the ECC engine 110 to perform high-speed MAC computation.

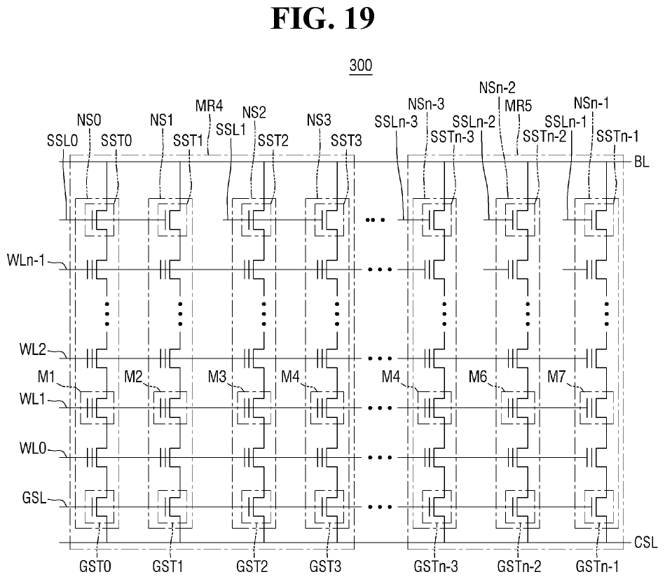

FIG. 19 is an exemplary diagram of the memory cell array that applies simultaneous program to different memory cells according to some embodiments of the present invention. Referring to FIG. 19, the memory cell array 300 includes a fourth merge region MR4 and a fifth merge region MR5.

For example, the fourth merge region MR4 may be a region for programming a piece of data in the first memory cell M1 and the second memory cell M2, and for programming another piece of data in the third memory cell M3 and the fourth memory cell M4. That is, the first string select transistor SST0 and the second string select transistor SST1 may be connected to each other by the first string select line SSL0 in the fabricating process, and the third string select transistor SST2 and the fourth string select transistor SST3 may be connected to each other by the second string select line SSL1 in the fabricating process.

The fifth merge region MR5 may be a region for programming a piece of data from the fifth memory cell M5 to the seventh memory cell M7. However, unlike the second merge region MR2 of FIG. 18, the fifth merge region MR5 does not connect the n−3^{rd} string select transistor SSTn−3 to the n−1^{st} string select transistor SSTn−1 by a single source select line, and may simultaneously apply the driving voltage.

Therefore, in the present embodiment, by determining the importance of data, since data of high importance may be programmed in the fourth merge region MR4, and data of low importance may be programmed in the fifth region MR5, it is possible to efficiently utilize the memory cell array 300. Also, the dispersions of each logical state may not overlap each other. As a result, the computing NAND device 100 of FIG. 1 may communicate directly with the controller 120 without going through the ECC engine 110 to perform high-speed MAC computation.

The number of strings in the above-mentioned region, that is, the first merge region MR1 to the fifth merge region MR5 and the first separate region SR1 is not limited to the number represented in the aforementioned drawings (FIGS. 17 to 19), and the number may be freely changed as necessary.

In concluding the detailed description, those skilled in the art will appreciate that many fluctuations and modifications may be made to the preferred embodiments without substantially departing from the principles of the present invention. Therefore, the disclosed preferred embodiments of the invention are used in a generic and descriptive sense only and not for purposes of limitation.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

1. A memory cell array comprising:
a first string including a first memory cell;
a second string including a second memory cell connected to the first memory cell by a first word line; and
a common source line (CSL) to which the first and second strings are connected,
wherein first data is simultaneously programmed in the first and second memory cells.

2. The memory cell array of claim 1, wherein the first string includes a first string select transistor (SST),
the second string includes a second string select transistor, and
a voltage is simultaneously applied to the first and second string select transistors.

3. The memory cell array of claim 2, wherein the first and second string select transistors are connected by a first string select line (SSL).

4. The memory cell array of claim 3, wherein the first and second memory cells are connected by the first word line, and
the memory cell array further comprises a third memory disposed in a third string including a third string select transistor connected by a second string select line.

5. The memory cell array of claim 1, further comprising:
a third string including a third memory cell connected to the first and second memory cells by the first word line,
wherein the first data is not programmed in the third string.

6. The memory cell array of claim 5, wherein each of the first to third memory cells has first to third threshold voltages, and
the first to third threshold voltages have different values from each other.

7. A nonvolatile memory device comprising:
a memory cell array which includes a first string including a first memory cell, and a second string including a second memory cell connected to the first memory cell by a same word line; and
a control unit,
wherein the control unit receives input data, classifies a part of the input data as first data, and simultaneously programs the first data in the first and second memory cells.

8. The nonvolatile memory device of claim 7, further comprising:
a row decoder,
wherein the first and second memory cells are connected by a first word line,
the control unit transmits a first program command for programming the first data to the row decoder, and
the row decoder receives the first program command, and transmits a first program voltage according to the first data program command to the first word line.

9. The nonvolatile memory device of claim 8, wherein the control unit includes a determine unit,
the control unit transmits the received input data to the determine unit, and
the determine unit determines importance of the received input data, classifies a part of the input data of high importance into the first data, and transmits the classified first data to the control unit.

10. The nonvolatile memory device of claim 9, further comprising:
a third string including a third memory cell,
wherein the third memory cell is connected to the first word line,
the determine unit determines importance of the received input data to classify data, which is more important than the first data, into second data,
the control unit transmits a second program command for programming the second data to the row decoder, and
the row decoder receives the second data program command, and transmits a second program voltage according to the second program command to the first word line.

11. The nonvolatile memory device of claim 7, wherein the memory cell array includes a first merge region and a separate region,
the first merge region includes a plurality of strings,
the separate region includes a single string, and
the first and second memory cells are included in the first merge region.

12. The nonvolatile memory device of claim 11, further comprising:
a third string,
wherein the first to third strings are connected to first to third string select transistors, respectively,
the first merge region includes the first and second string select transistors,
the separate region includes the third string select transistor, and
ON-voltage is simultaneously applied to the first and second string select transistors.

13. The nonvolatile memory device of claim 12, further comprising:
a fourth string select transistor to which a fourth string is connected,
wherein the separate region includes the fourth string select transistor,
the ON-voltage is applied to the third and fourth string select transistors at different times.

14. The nonvolatile memory device of claim 12, wherein the first and second string select transistors are connected by a first string select line.

15. A nonvolatile memory device comprising:
first to third memory cells included in each of first to third strings;
first to third string select transistors included in each of the first to third strings;
a first word line which connects the first to third memory cells; and
a control unit which turns the first and second string select transistors ON for a first section, keeps the third string select transistor in an OFF state for the first section, and applies a program voltage to the first word line for a second section.

16. The nonvolatile memory device of claim 15, further comprising:
a second word line which is maintained in the OFF state during application of the program voltage to the first word line.

17. The nonvolatile memory device of claim 15, further comprising:
a memory cell array which includes the first to third memory cells, the first to third string select transistors, and the first word line.

18. The nonvolatile memory device of claim 17, further comprising:
a memory NAND device which stores data; and
a computing NAND device which performs computation,
wherein the computing NAND device further includes the control unit, the memory cell array, and a row decoder.

19. The nonvolatile memory device of claim 18, wherein the control unit includes a determine unit,
the determine unit determines whether the data received by the control unit is important data and transmits determined result to the control unit, and
if the data is important data as a result of the determination, the control unit turns the first and second string select transistors ON at a first time through the row decoder.

20. The nonvolatile memory device of claim 15, the first and second string select transistors are connected by a first string select line.

21.-30. (canceled)
